(19) United States
(12) Patent Application Publication
(10) Pub. No.: US 2023/0282563 A1
(43) Pub. Date: Sep. 7, 2023

(54) SEMICONDUCTOR DEVICE

(71) Applicant: FUJI ELECTRIC CO., LTD., Kawasaki-shi (JP)

(72) Inventor: Sota YAMAGUCHI, Matsumoto-city (JP)

(73) Assignee: FUJI ELECTRIC CO., LTD., Kawasaki-shi (JP)

(21) Appl. No.: 18/159,500

(22) Filed: Jan. 25, 2023

(30) Foreign Application Priority Data
Mar. 3, 2022 (JP) 2022-032233

(51) Int. Cl. H01L 23/498; H01L 23/538; H01L 25/07; H01L 23/00

(52) U.S. Cl. CPC H01L 23/49844; H01L 23/5386; H01L 24/32; H01L 24/40; H01L 25/072; H01L 2224/32155; H01L 2224/40153; H01L 2224/40225

(57) ABSTRACT

A semiconductor device includes a semiconductor chip that has a first main electrode on a rear surface thereof and a second main electrode on a front surface thereof, and a wiring layer electrically connected to at least one of the first main electrode or the second main electrode. The wiring layer includes a conductive member that is disposed on a front surface of the wiring layer.

### CROSS-REFERENCE TO RELATED APPLICATION

This application is based upon and claims the benefit of priority of the prior Japanese Patent Application No. 2022-032233, filed on Mar. 3, 2022, the entire contents of which are incorporated herein by reference.

### BACKGROUND OF THE INVENTION

### 1. Field of the Invention

The embodiments discussed herein relate to a semiconductor device.

### 2. Background of the Related Art

Semiconductor devices include power devices and are used as power conversion devices. These power devices include semiconductor chips. Examples of the semiconductor chips include insulated gate bipolar transistors (IGBTs) and power metal-oxide-semiconductor field-effect transistors (MOSFETs). Such a semiconductor device includes at least a semiconductor chip and an insulated circuit board on which the semiconductor chip is disposed. In this case, the semiconductor chip is bonded to a circuit pattern included in the insulated circuit board via a bonding member (for example, solder) .

In addition, smaller semiconductor devices have been manufactured. To achieve downsizing of a semiconductor device, for example, the size of an insulated circuit board included in the semiconductor device needs to be reduced. To reduce the size of the insulated circuit board, the area of a circuit pattern also needs to be reduced.

### International Publication Pamphlet No. WO 2019/235097

However, if the area of a circuit pattern is reduced, the wiring resistance with respect to a current that flows through the circuit pattern increases. In addition, if the wiring resistance increases, Joule heat is generated at the corresponding portion. If a semiconductor chip is disposed near the heated portion, the temperature of the semiconductor chip rises, and the semiconductor chip could consequently break down.

To dispose more semiconductor chips on an insulated circuit board, a circuit pattern needs to have a sufficient area. If more semiconductor chips are disposed, a greater current is outputted from or inputted to the semiconductor chips. In this case, if a circuit pattern does not have a sufficient area, the wiring resistance with respect to a current that flows through the circuit pattern could increase. In this case, too, a portion having the increased wiring resistance is heated, and this heat could cause a failure as described above.

### SUMMARY OF THE INVENTION

In one aspect of the embodiments, there is provided a semiconductor device including: a semiconductor chip that has a first main electrode on a rear surface thereof and a second main electrode on a front surface thereof; and a wiring layer electrically connected to at least one of the first main electrode or the second main electrode, the wiring layer including a conductive member disposed on a front surface thereof.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor module according to a first embodiment;

FIG. 2 is a plan view of an insulated circuit board included in the semiconductor module according to the first embodiment;

FIG. 3 is a first sectional view of the semiconductor module according to the first embodiment;

FIG. 4 is a second sectional view of the semiconductor module according to the first embodiment;

FIG. 5 is a first sectional view of a main part of a semiconductor module according to variation 1-1 of the first embodiment;

FIG. 6 is a second sectional view of the main part of the semiconductor module according to variation 1-1 of the first embodiment;

FIG. 7 is a sectional view of a main part of a semiconductor module according to variation 1-2 of the first embodiment;

FIG. 8 is a sectional view of a main part of a semiconductor module according to variation 1-3 of the first embodiment;

FIG. 9 is a first sectional view of a main part of a semiconductor module according to a second embodiment;

FIG. 10 is a second sectional view of the main part of the semiconductor module according to the second embodiment;

FIG. 11 is a first sectional view of a main part of a semiconductor module according to variation 2-1 of the second embodiment;

FIG. 12 is a second sectional view of the main part of the semiconductor module according to variation 2-1 of the second embodiment; and

FIG. 13 is a sectional view of a main part of a semiconductor module according to variation 2-2 of the second embodiment.

### DETAILED DESCRIPTION OF THE INVENTION

Hereinafter, embodiments will be described with reference to the accompanying drawings. In the following description, regarding a semiconductor module 1 in drawings, terms “front surface” and “upper surface” each represent an X-Y surface facing upward (+Z direction). Likewise, regarding the semiconductor module 1 in drawings, a term “up” represents an upward direction (+Z direction). Regarding the semiconductor module 1 in drawings, terms “rear surface” and “lower surface” each represent an X-Y surface facing downward (-Z direction). Likewise, regarding the semiconductor module 1 in drawings, a term “down” represents a downward direction (-Z direction). In the other drawings, too, the above terms represent their respective directions, as needed. Regarding the semiconductor module 1 in drawings, a term “higher level” represents a higher location (+Z direction). Likewise, regarding the semiconductor module 1 in drawings, a term “lower level” represents a lower location (-Z direction). The terms “front surface”, “upper surface”, “up”, “rear surface”, “lower surface”, “down”, and “side surface” are only expressions used for the purpose of convenience to determine relative positional relationships and do not limit the technical concept of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in material represents 80 vol% or more of the material, this component will be referred to as the “main component” of the material. When two objects are described as “forming an approximately right angle” or as “being approximately perpendicular to each other”, the angle formed by these two objects is between 85° and 95°, inclusive.

### First Embodiment

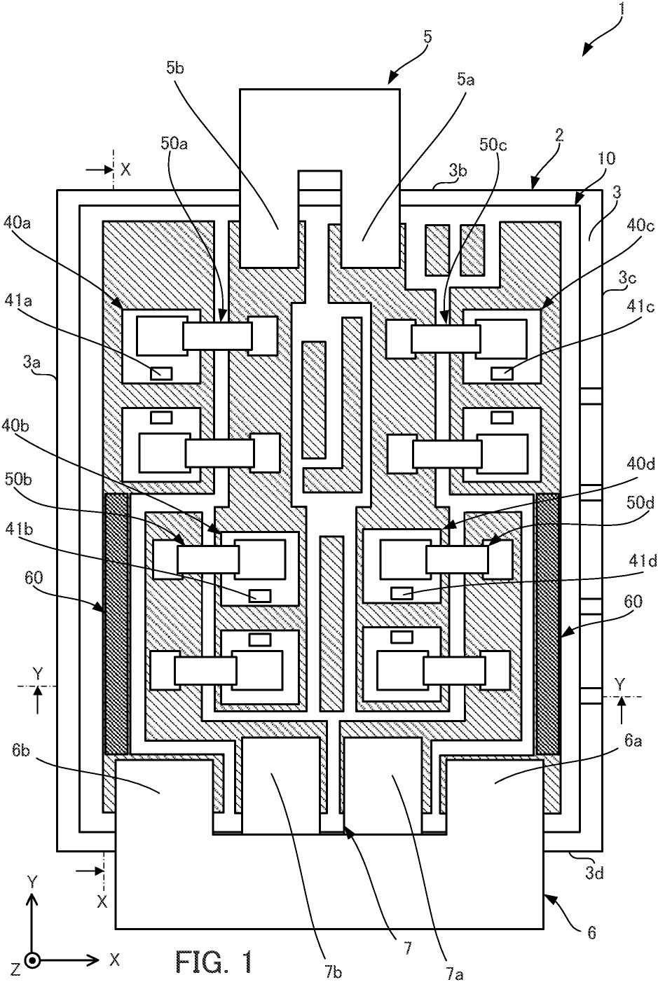

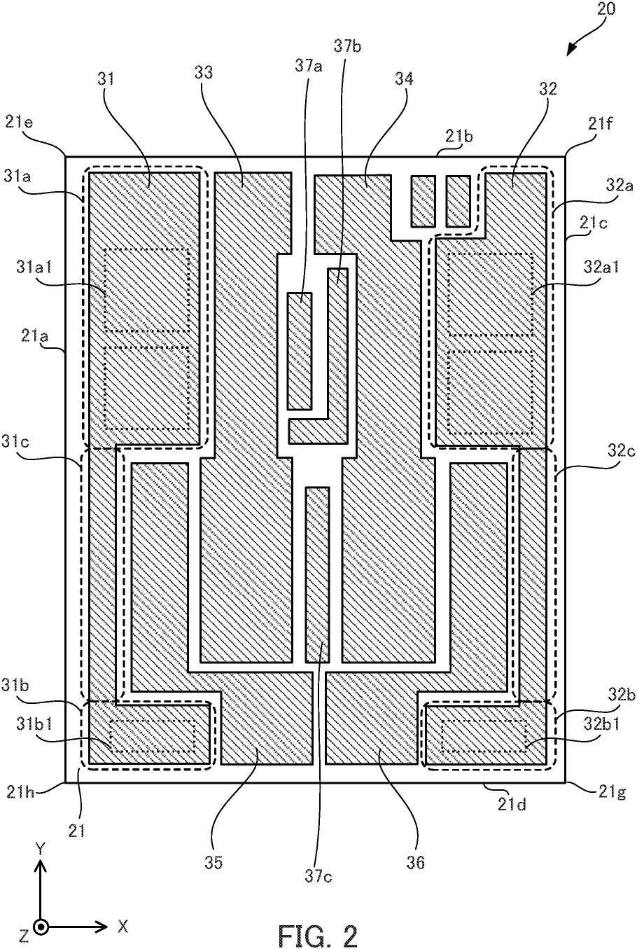

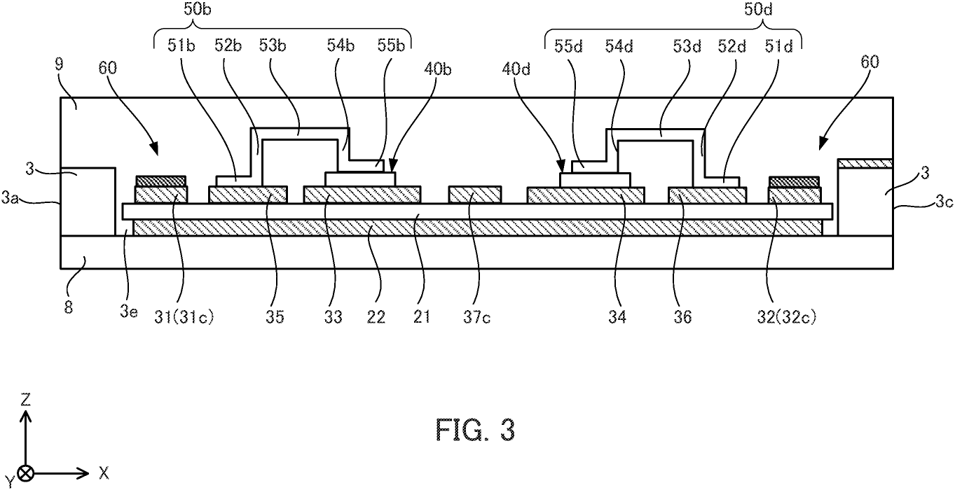

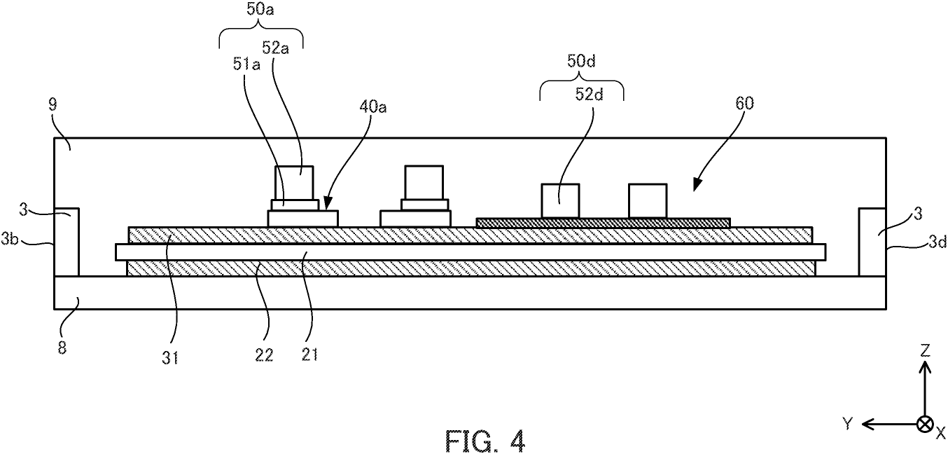

A semiconductor module according to a first embodiment will be described with reference to FIGS. 1 to 4. FIG. 1 is a plan view of the semiconductor module according to the first embodiment, and FIG. 2 is a plan view of an insulated circuit board included in the semiconductor module according to the first embodiment. FIGS. 3 and 4 are each a sectional view of the semiconductor module according to the first embodiment. A sealing member 9 is not illustrated in the semiconductor module 1 in FIG. 1. FIG. 3 is a sectional view taken along a dashed-dotted line Y-Y in FIG. 1. FIG. 4 is a sectional view taken along a dashed-dotted line X-X in FIG. 1.

A semiconductor device according to the first embodiment includes an equivalent circuit constituting an inverter circuit. This semiconductor device includes a plurality of semiconductor modules 1. For example, the semiconductor device is structured by disposing three semiconductor modules 1 of the U phase, the V phase, and the W phase side by side in this order in an X direction.

The individual semiconductor module 1 includes a semiconductor unit 10, a base substrate 8 on which the semiconductor unit 10 is disposed, and a case 2 that is disposed on the base substrate 8 and that stores the semiconductor unit 10. In addition, the semiconductor module 1 includes the sealing member 9 with which the case 2 is filled and that seals the semiconductor unit 10.

The case 2 includes an outer frame 3, an output terminal 5, a positive terminal 6, and a negative terminal 7. The outer frame 3 has an approximately rectangular shape in plan view and has a pair of long sides 3a and 3c and a pair of short sides 3b and 3d. The outer frame 3 has a storage portion 3e whose four sides are surrounded by the pair of long sides 3a and 3c and the pair of short sides 3b and 3d. The semiconductor unit 10 is stored in the storage portion 3e, and the storage portion 3e is sealed by the sealing member 9.

The output terminal 5 is disposed on the short side 3b of the outer frame 3. The output terminal 5 has a U shape in plan view. That is, the output terminal 5 is divided into two portions and includes inner bonding portions 5a and 5b at tips of the two portions. The inner bonding portion 5a of the output terminal 5 is directly connected to a circuit pattern 34. The inner bonding portion 5b of the output terminal 5 is directly connected to a circuit pattern 33.

The positive terminal 6 and the negative terminal 7 used as input terminals are disposed on the short side 3d and are opposite to the output terminal 5 via the storage portion 3e. The positive terminal 6 has a U shape in plan view. That is, the positive terminal 6 is divided into two portions and includes inner bonding portions 6a and 6b at tips of the two portions. The inner bonding portion 6a of the positive terminal 6 is directly connected to a circuit pattern 32. The inner bonding portion 6b of the positive terminal 6 is directly connected to a circuit pattern 31. The negative terminal 7 has a U shape in plan view. That is, the negative terminal 7 is divided into two portions and includes inner bonding portions 7a and 7b at tips of the two portions. The inner bonding portion 7a of the negative terminal 7 is directly connected to a circuit pattern 36. The inner bonding portion 7b of the negative terminal 7 is directly connected to a circuit pattern 35.

Each of the inner bonding portions 5a, 6a, 7a, 5b, 6b, and 7b may be bonded to the corresponding one of the circuit patterns 31 to 36 by using a bonding member or ultrasonic bonding. Solder or sintered material is used as the bonding member. As this solder, lead-free solder is used. The main component of the lead-free solder is, for example, an alloy containing at least two of tin, silver, copper, zinc, antimony, indium, and bismuth. The solder may also contain additive, which is, for example, nickel, germanium, cobalt, or silicon. Since solder containing such additive as described above has improved wettability, luster, and bonding strength, the reliability is improved. As the sintered material, for example, metal material containing silver, copper, or an alloy containing at least one of these kinds is used.

By bonding the inner bonding portions 5a, 6a, 7a, 5b, 6b, and 7b as described above, the output terminal 5, the positive terminal 6, and the negative terminal 7 are electrically connected to semiconductor chips 40a, 40b, 40c, and 40d of the semiconductor unit 10 stored in the storage portion 3e. Specifically, the positive terminal 6 (the inner bonding portions 6a and 6b) is electrically connected to input electrodes of the semiconductor chips 40c and 40a via the circuit patterns 32 and 31.

The negative terminal 7 (the inner bonding portions 7a and 7b) is electrically connected to output electrodes of the semiconductor chips 40d and 40b via the circuit patterns 36 and 35 and lead frames 50d and 50b.

The output terminal 5 (the inner bonding portions 5a and 5b) is electrically connected to input electrodes of the semiconductor chips 40d and 40b via the circuit patterns 34 and 33. In addition, the output terminal 5 (the inner bonding portions 5a and 5b) is electrically connected to output electrodes of the semiconductor chips 40c and 40a via the circuit patterns 34 and 33 and lead frames 50c and 50a.

The output terminal 5, the positive terminal 6, and the negative terminal 7 are made of material having excellent electrical conductivity. Examples of the metal material include copper, aluminum, and an alloy containing at least one of these kinds. The surface of each of the output terminal 5, the positive terminal 6, and the negative terminal 7 may be plated to improve its corrosion resistance. The material used for this plating is, for example, nickel, a nickel-phosphorus alloy, or a nickel-boron alloy.

The sealing member 9 seals the semiconductor unit 10 disposed in the storage portion 3e. The sealing member 9 may be thermosetting resin such as epoxy resin, phenolic resin, maleimide resin, or polyester resin. Preferably, the thermosetting resin is epoxy resin. Filler may be added to the sealing member 9. The filler is highly thermally conductive ceramic material having an insulating property. Examples of the filler include silicon oxide, aluminum oxide, boron nitride, and aluminum nitride. The amount of filler contained is between 10% by volume and 70% by volume, inclusive, of the entire sealing member 9.

The base substrate 8 is formed in a flat plate and has a rectangular shape in plan view. In addition, the base substrate 8 may cover the storage portion 3e inside the case 2 (the outer frame 3) from the rear surface of the case 2 in plan view. The base substrate 8 may be made of metal material having excellent thermal conductivity. Examples of the material include aluminum, iron, silver, copper, and an alloy containing at least one of these kinds. Examples of the alloy include a metal composite of aluminum-silicon nitride (Al-SiC) and a metal composite of magnesium-silicon nitride (Mg-SiC). The surface of the base substrate 8 may be plated by using, for example, plating material to improve its corrosion resistance. Examples of the plating material include nickel and a nickel alloy.

In addition, a cooling unit (not illustrated) may be attached to the rear surface of the base substrate 8. The cooling unit in this case is made of metal material having excellent thermal conductivity, for example. Examples of the metal material include aluminum, iron, silver, copper, and an alloy containing at least one of these kinds. The cooling unit is a heatsink having at least one fin, a water cooling jacket, or the like. The base substrate 8 may be formed integrally with the cooling unit as described above.

The semiconductor unit 10 includes an insulated circuit board 20, the semiconductor chip 40a to 40d, and the lead frames 50a to 50d. The insulated circuit board 20 has a rectangular shape in plan view. The insulated circuit board 20 includes an insulating plate 21, a wiring layer formed on the front surface of the insulating plate 21, and a metal plate 22 formed on the rear surface of the insulating plate 21. The wiring layer corresponds to the plurality of circuit patterns 31 to 36 and circuit patterns 37a to 37c, for example. The outer shape of the plurality of circuit patterns 31 to 36 and 37a to 37c and the outer shape of the metal plate 22 are smaller than the outer shape of the insulating plate 21 and are located inside the outer shape of the insulating plate 21 in plan view. The illustrated shapes, number, and sizes of the plurality of circuit patterns 31 to 36 and 37a to 37c are only examples.

The insulating plate 21 has a rectangular shape in plan view. The insulating plate 21 may have chamfered or rounded corner portions, for example. Four sides of the insulating plate 21 are a long side 21a, a short side 21b, a long side 21c, and a short side 21d, which are its outer periphery sides. In addition, the insulating plate 21 has corner portions 21e, 21f, 21g, and 21h. The corner portions 21e is formed by the long side 21a and the short side 21b. The corner portions 21f is formed by the short side 21b and the long side 21c. The corner portions 21g is formed by the long side 21c and the short side 21d. The corner portions 21h is formed by the short side 21d and the long side 21a. The insulating plate 21 is made of ceramic material having good thermal conductivity. For example, the ceramic material contains aluminum oxide, aluminum nitride, or silicon nitride as its main component. In addition, the insulating plate 21 has a thickness between 0.2 mm and 2.0 mm, inclusive.

The metal plate 22 has a rectangular shape in plan view. The metal plate 22 may have chamfered or rounded corner portions, for example. The metal plate 22 is smaller than the insulating plate 21 and is formed on the entire rear surface of the insulating plate 21, excepting the edge portions of the insulating plate 21. The metal plate 22 contains metal material having excellent thermal conductivity as its main component. Examples of the metal material include copper, aluminum, and an alloy containing at least one of these kinds. The metal plate 22 has a thickness between 0.1 mm and 2.0 mm, inclusive. The metal plate may be plated to improve its corrosion resistance. The material used for this plating is, for example, nickel, a nickel-phosphorus alloy, or a nickel-boron alloy.

The circuit patterns 31 to 36 and 37a to 37c are formed on the entire front surface of the insulating plate 21, excepting the edge portions of the insulating plate 21. Preferably, in plan view, end portions of the circuit pattern 31 to 36 and 37a to 37c, the end portions facing the outer periphery of the insulating plate 21, overlap with end portions of the metal plate 22, the end portions facing the outer periphery of the insulating plate 21. Thus, the insulated circuit board 20 maintains the stress balance between the circuit pattern 31 to 36 and 37a to 37c and the metal plate 22 disposed on the rear surface of the insulating plate 21. As a result, occurrence of excessive warpage of the insulating plate 21 and occurrence of damage such as a crack in the insulating plate 21 are reduced. Areas indicated by dashed lines illustrated in the circuit pattern 31 represent chip areas 31a1 of the two semiconductor chips 40a. Areas indicated by dashed lines illustrated in the circuit pattern 32 represent chip areas 32a1 of the two semiconductor chips 40c. For example, the circuit patterns 31 to 36 and 37a to 37c each have a thickness between 0.1 mm and 2.0 mm, inclusive. The circuit patterns 31 to 36 and 37a to 37c are each made of metal material having excellent electrical conductivity. Examples of the metal material include copper, aluminum, and an alloy containing at least one of these kinds. The surface of each of the circuit patterns 31 to 36 and 37a to 37c may be plated to improve its corrosion resistance. The material used for this plating is, for example, nickel, a nickel-phosphorus alloy, or a nickel-boron alloy.

The circuit pattern 31 is formed near the long side 21a of the insulating plate 21 from the short side 21b to the short side 21d along the long side 21a. The circuit pattern 31 includes a first portion 31a, a second portion 31b, and a wiring portion 31c.

The first portion 31a is formed near the short side 21b along the long side 21a. In the first portion 31a, the chip areas 31a1 in which the semiconductor chips 40a are disposed are set along the long side 21a. The number of chip areas 31a1 is not limited to any particular number. In FIG. 2, two chip areas 31a1 are set. The chip areas 31a1 are set away from the short side 21b within the first portion 31a.

The second portion 31b is formed near the short side 21d along the long side 21a. A terminal area 31b1, to which the inner bonding portion 6b of the positive terminal 6 is boned, is set near the short side 21d. The first portion 31a and the second portion 31b have approximately the same width in the ±X direction.

The wiring portion 31c connects the first portion 31a and the second portion 31b and is formed near the long side 21a along the long side 21a. The width of the wiring portion 31c in the ±X direction is less than the width of the first portion 31a and the second portion 31b in the ±X direction.

The circuit pattern 32 and the circuit pattern 31 are approximately symmetric with respect to a straight line extending in the ±Y direction. The circuit pattern 32 is formed near the long side 21c of the insulating plate 21 from the short side 21b to the short side 21d along the long side 21c. The circuit pattern 32 includes a first portion 32a, a second portion 32b, and a wiring portion 32c.

The first portion 32a is formed near the short side 21b along the long side 21c. In the first portion 32a, the chip areas 32a1 in which the semiconductor chips 40c are disposed are set along the long side 21c. The number of chip areas 32a1 is not limited to any particular number. In FIG. 2, two chip areas 32a1 are set. The chip areas 32a1 are set away from the short side 21b within the first portion 32a. In addition, the first portion 32a has a notch area near the short side 21b, the notch area being located at a corner portion of the first portion 32a in the -X direction.

The second portion 32b is formed near the short side 21d along the long side 21c. A terminal area 32b1, to which the inner bonding portion 6a of the positive terminal 6 is bonded, is set near the short side 21d. The first portion 32a and the second portion 32b have approximately the same width in the ±X direction.

The wiring portion 32c connects the first portion 32a and the second portion 32b and is formed near the long side 21c along the long side 21c. The width of the wiring portion 32c in the ±X direction is less than the width of the first portion 32a and the second portion 32b in the ±X direction.

The circuit pattern 33 is adjacent to the first portion 31a of the circuit pattern 31 and extends from the short side 21b in the -Y direction in parallel to the long side 21a. The end portion of the circuit pattern 33 in the -Y direction is away from the short side 21d. The side of the circuit pattern 33 in the direction of the long side 21c has a concave portion.

The circuit pattern 34 and the circuit pattern 33 are approximately symmetric with respect to a straight line extending in the ±Y direction. The circuit pattern 34 is adjacent to the first portion 32a of the circuit pattern 32 and extends from the short side 21b in the -Y direction in parallel to the long side 21c. The end portion of the circuit pattern 34 in the -Y direction is away from the short side 21d. The side of the circuit pattern 34 in the direction of the long side 21a has a concave portion. In addition, the circuit pattern 34 has a notch area near the short side 21b, the notch area being located at a corner portion of the circuit pattern 34 in the +X direction.

While the semiconductor chips 40b and 40d are also disposed in the circuit patterns 33 and 34, respectively, the corresponding chip areas are not illustrated. The semiconductor chips 40b are disposed in their respective locations on the circuit pattern 33 as illustrated FIG. 1. Likewise, the semiconductor chips 40d are disposed in their respective locations on the circuit pattern 34 as illustrated FIG. 1.

The circuit pattern 35 is disposed in an area surrounded by the second portion 31b and the wiring portion 31c of the circuit pattern 31, the short side 21d, and the circuit pattern 33. That is, the circuit pattern 35 has an approximately L shape.

The circuit pattern 36 and the circuit pattern 35 are approximately symmetric with respect to a straight line extending in the ±Y direction. The circuit pattern 36 is disposed in an area surrounded by the second portion 32b and the wiring portion 32c of the circuit pattern 32, the short side 21d, and the circuit pattern 34. That is, the circuit pattern 36 has an approximately L shape.

The circuit pattern 37a has an I shape in plan view and is disposed in an area surrounded by the concave portions of the circuit patterns 33 and 34. The circuit pattern 37a is formed near the circuit pattern 33 in parallel to the long side 21a. The circuit pattern 37b has an L shape in plan view and is disposed in the area surrounded by the concave portions of the circuit patterns 33 and 34. The circuit pattern 37b is formed near the circuit pattern 34 in parallel to the long side 21c. The circuit pattern 37b is disposed to surround the circuit pattern 37a. The circuit pattern 37c has an I shape in plan view and is disposed between the circuit patterns 33 and 34 in parallel to the long sides 21a and 21c.

For example, a direct copper bonding (DCB) substrate or an active metal brazed (AMB) substrate may be used as the insulated circuit board 20 having the above structure. The insulated circuit board 20 transfers the heat, which will be described below, generated by the semiconductor chips 40a to 40d to the rear surface of the insulated circuit board 20 via the circuit patterns 31 to 34, the insulating plate 21, and the metal plate 22 and releases the heat to the outside.

In addition, the insulated circuit board 20 includes conductive members 60. According to the first embodiment, the conductive members 60 each have a flat plate shape. One of the conductive members 60 is formed on the front surface of the wiring portion 31c of the circuit pattern 31, and the other conductive member 60 is formed on the front surface of the wiring portion 32c of the circuit pattern 32. The width of the individual conductive member 60 in the ±X direction may be the same as or less than the width of the corresponding one of the wiring portions 31c and 32c in the ±X direction. One of the conductive members 60 is disposed between the connection portion of the wiring portion 31c and the first portion 31a and the connection portion of the wiring portion 31c and the second portion 31b. The other conductive member 60 is disposed between the connection portion of the wiring portion 32c and the first portion 32a and the connection portion of the wiring portion 32c and the second portion 32b. The height of the individual conductive member 60 may be approximately the same as the thickness of the semiconductor chips 40a to 40d. As will be described below, currents that flow through the wiring portions 31c and 32c also flow through their respective conductive members 60. Thus, the wiring resistance of each of the wiring portions 31c and 32c is reduced. The currents flowing through the conductive members 60 mainly flow through the lower portions of their respective conductive members 60 (near the circuit patterns 31 and 32). Thus, the conductive members 60 do not need to be excessively thick. The conductive members 60 contain, as their main component, material having electrical conductivity and thermal conductivity equal to or more than those of the wiring portions 31c and 32c. For example, the material is copper or a copper alloy. One of the conductive members 60 is bonded to the front surface of the wiring portion 31c of the circuit pattern 31 by using a bonding member. The other conductive member 60 is bonded to the front surface of the wiring portion 32c of the circuit pattern 32 by using a bonding member. Solder or sintered material is used as the bonding member. As this solder, lead-free solder is used. The main component of the lead-free solder is, for example, an alloy containing at least two of tin, silver, copper, zinc, antimony, indium, and bismuth. The solder may also contain additive, which is, for example, nickel, germanium, cobalt, or silicon. Since solder containing such additive has improved wettability, luster, and bonding strength, the reliability is improved. As the sintered material, for example, metal material containing silver or a silver alloy is used.

The semiconductor chips 40a to 40d are each a power device made of silicon carbide. Examples of the power devices include power MOSFETs. These semiconductor chips 40a to 40d include drain electrodes as input electrodes (main electrodes) on their respective rear surfaces. In addition, these semiconductor chips 40a to 40d include gate electrodes as control electrodes 41a to 41d and source electrodes as output electrodes (main electrodes) on their respective front surfaces.

Alternatively, the semiconductor chips 40a to 40d may each be a power device made of silicon. In this case, examples of the power devices include reverse conducting (RC)-IGBTs. An RC-IGBT is formed by forming an IGBT as a switching element and a free-wheeling diode (FWD) as a diode element in a single chip. For example, these semiconductor chip 40a to 40d include collector electrodes as input electrodes (main electrodes) on their respective rear surfaces and include gate electrodes as control electrodes and emitter electrodes as output electrodes (main electrodes) on their respective front surfaces.

As illustrated in FIG. 1, the semiconductor chips 40a to 40d are disposed on the circuit patterns 31, 33, 32, and 34, respectively. According to the first embodiment, two semiconductor chips are disposed on each of these circuit patterns. In this case, the semiconductor chips 40a are disposed such that the control electrodes 41a face each other. The same applies to the semiconductor chips 40b to 40d and the control electrodes 41b to 41d. The semiconductor chips 40a to 40d are also bonded to the circuit patterns 31, 33, 32, and 34, respectively, by using the above-described bonding member.

The lead frames 50a electrically connect the output electrodes on the front surfaces of the semiconductor chips 40a to the circuit pattern 33. The lead frames 50b electrically connect the output electrodes on the front surfaces of the semiconductor chips 40b to the circuit pattern 35. The lead frames 50c electrically connect the output electrodes on the front surfaces of the semiconductor chips 40c to the circuit pattern 34. The lead frames 50d electrically connect the output electrodes on the front surfaces of the semiconductor chips 40d to the circuit pattern 36. For example, as illustrated in FIG. 3, the individual lead frame 50b includes a pattern bonding portion 51b, a first vertical linkage portion 52b, a horizontal linkage portion 53b, a second vertical linkage portion 54b, and a chip bonding portion 55b. Likewise, the individual lead frame 50d includes a pattern bonding portion 51d, a first vertical linkage portion 52d, a horizontal linkage portion 53d, a second vertical linkage portion 54d, and a chip bonding portion 55d. The individual pattern bonding portion 51b is bonded to the circuit pattern 35, and the individual pattern bonding portion 51d is bonded to the circuit pattern 36. The individual first vertical linkage portion 52b is connected to an end portion of the corresponding pattern bonding portion 51b and extends vertically. The individual first vertical linkage portion 52d is connected to an end portion of the corresponding pattern bonding portion 51d and extends vertically. The individual horizontal linkage portion 53b extends from an end portion of the corresponding first vertical linkage portion 52b and extends in the direction of the corresponding semiconductor chip 40b. The individual horizontal linkage portion 53d extends from an end portion of the corresponding first vertical linkage portion 52d and extends in the direction of the corresponding semiconductor chip 40d. The individual second vertical linkage portion 54b extends from an end portion of the corresponding horizontal linkage portion 53b vertically in the direction of the corresponding semiconductor chip 40b. The individual second vertical linkage portion 54d extends from an end portion of the corresponding horizontal linkage portion 53d vertically in the direction of the corresponding semiconductor chip 40d. The individual chip bonding portion 55b is bonded to the output electrode of the corresponding semiconductor chip 40b and has one end portion connected to the corresponding second vertical linkage portion 54b. The individual chip bonding portion 55d is bonded to the output electrode of the corresponding semiconductor chip 40d and has one end portion connected to the corresponding second vertical linkage portion 54d.

The lead frames 50a and 50c also include pattern bonding portions, first vertical linkage portions, horizontal linkage portions, second vertical linkage portions, and chip bonding portions. FIG. 4 illustrates pattern bonding portions 51a and first vertical linkage portions 52a of the lead frames 50a. The detailed description of the lead frames 50a and 50c will be omitted.

The chip bonding portions of the lead frames 50a to 50d may be bonded to the output electrodes of the semiconductor chips 40a to 40d by using the above-described bonding member. The pattern bonding portions of the lead frames 50a to 50d may be bonded to the circuit patterns 33, 35, 34, and 36 by using the above-described bonding member or ultrasonic bonding.

The lead frames 50a to 50d are each made of material having excellent electrical conductivity and thermal conductivity. Examples of the material include copper, aluminum, and an alloy containing at least one of these kinds. The surface of each of the lead frames 50a to 50d may be plated to improve its corrosion resistance. The material used for this plating is, for example, nickel, a nickel-phosphorus alloy, or a nickel-boron alloy.

The control electrodes 41a of the semiconductor chips 40a are connected to the circuit pattern 37a by using wiring members not illustrated. The control electrodes 41c of the semiconductor chips 40c are connected to the circuit pattern 37b by using wiring members not illustrated. The control electrodes 41b and 41d of the semiconductor chips 40b and 40d are connected to the circuit pattern 37c by using wiring members not illustrated. Control signals are inputted to these circuit patterns 37a to 37c from the outside.

The semiconductor module 1 having the above structure operates when an external high potential terminal is connected to the positive terminal 6, an external low potential terminal is connected to the negative terminal 7, and a control signal is inputted. In particular, based on ON or OFF of the control signal to the semiconductor chips 40a to 40d, a current flows from the inner bonding portions 6a and 6b of the positive terminal 6 to the circuit pattern 32 and 31. The current that has flowed to the circuit pattern 32 flows from the second portion 32b to the input electrodes of the semiconductor chips 40c in the first portion 32a through the wiring portion 32c. In addition, the current that has flowed to the circuit pattern 31 flows from the second portion 31b to the input electrodes of the semiconductor chips 40a in the first portion 31a through the wiring portion 31c. The width of the wiring portion 32c is sufficiently narrower than the width of the first portion 32a and the second portion 32b. Likewise, the width of the wiring portion 31c is sufficiently narrower than the width of the first portion 31a and the second portion 31b. Thus, there are cases in which the temperature of the wiring portions 32c and 31c rises due to Joule heat. For example, the wiring portions 32c and 31c each have a width of 2.6 mm (in the ±X direction) and have a thickness of 0.4 mm, and a current of 600 A flows through the wiring portions 32c and 31c. In this case, without the conductive members 60, 60 W is lost in the wiring portions 32c and 31c, and the temperature rises by 30° C. or more. If the temperature rises in this way, even if the heat is released in the direction of the base substrate 8 disposed underneath, the semiconductor chips 40b and 40d disposed near the wiring portions 32c and 31c are not sufficiently cooled and could consequently break down.

According to the first embodiment, one of the conductive members 60 is disposed on the wiring portion 32c of the circuit pattern 32, and the other conductive member 60 is disposed on the wiring portion 31c of the circuit pattern 31. The current that flows through the wiring portion 32c also flows through the corresponding conductive member 60. Likewise, the current that flows through the wiring portion 31c also flows through the corresponding conductive member 60. Thus, the wiring portions 32c and 31c each have reduced wiring resistance and loss, and the rise in temperature due to Joule heat is also reduced. That is, it becomes possible to dispose the semiconductor chips 40b and 40d near the circuit patterns 32 and 31 that could be heated, and as a result, the freedom in disposing the semiconductor chips 40b and 40d is improved. There are cases in which reducing the volume of the circuit patterns 31 to 36 generates an area having increased wiring resistance. Even in such cases, by forming a conductive member 60 in this area, it becomes possible to reduce the rise in temperature. Thus, the first embodiment enables downsizing of the semiconductor module 1 while maintaining the reliability of the semiconductor module 1. The reduction of the volume of the circuit patterns 31 to 36 includes reduction of the width perpendicular to the current conduction direction in plan view and reduction of the thickness in sectional view.

Instead of the individual conductive member 60, one end portion and the other end portion of at least one wire may be attached to the wiring portion 32c or 31c of the circuit pattern 32 or 31 by bonding. However, if a wire is bonded to the wiring portion 32c or 31c by bonding, a bonding portion could be peeled from the wiring portion 32c or 31c. In contrast, in the case of the conductive members 60, occurrence of such peeling is reduced, compared with the above case in which wires are used.

In addition, only the wiring portions 32c and 31c of the circuit patterns 32 and 31 may be formed to be thicker than the other portions of the circuit patterns 32 and 31. However, in this case, it is difficult to form only certain portions of the circuit patterns 32 and 31 to be thicker than the other portions. In addition, because there is a limit to how much only these certain portions are thickened, the rise in temperature could not be sufficiently reduced.

The first embodiment has been described based on an example in which the conductive members 60 are disposed on the wiring portions 32c and 31c of the circuit patterns 32 and 31. However, if there is a portion where the temperature could rise as a result of a current flow, another conductive member 60 may be disposed on a circuit pattern other than the wiring portions 32c and 31c of the circuit patterns 32 and 31. Examples of the portion where the temperature could rise as a result of a current flow include the circuit patterns 31 to 36 electrically connected to the input electrodes and the output electrodes of the semiconductor chips 40a to 40d. The conductive members 60 may be disposed on the circuit patterns 31 to 36 (and areas included in the circuit patterns 31 to 36) .

The shape of the individual conductive member 60 in plan view corresponds to the shape of the corresponding one of the wiring portions 32c and 31c of the circuit patterns 32 and 31. Since the wiring portions 32c and 31c of the circuit patterns 32 and 31 according to the first embodiment each have a linear shape, the conductive members 60 each have a linear shape, too. If the shape of the wiring portion 32c or 31c in plan view is, for example, an L shape or a crank shape, the corresponding conductive member 60 has the corresponding shape.

The shape of the individual conductive member 60 is not limited to a flat plate shape. Hereinafter, variations indicating various modes of the conductive members 60 will be described. In each of the following variations, only the conductive members 60 differ. The other components of the semiconductor module 1 are the same as those in FIGS. 1 to 4.

### Variation 1-1

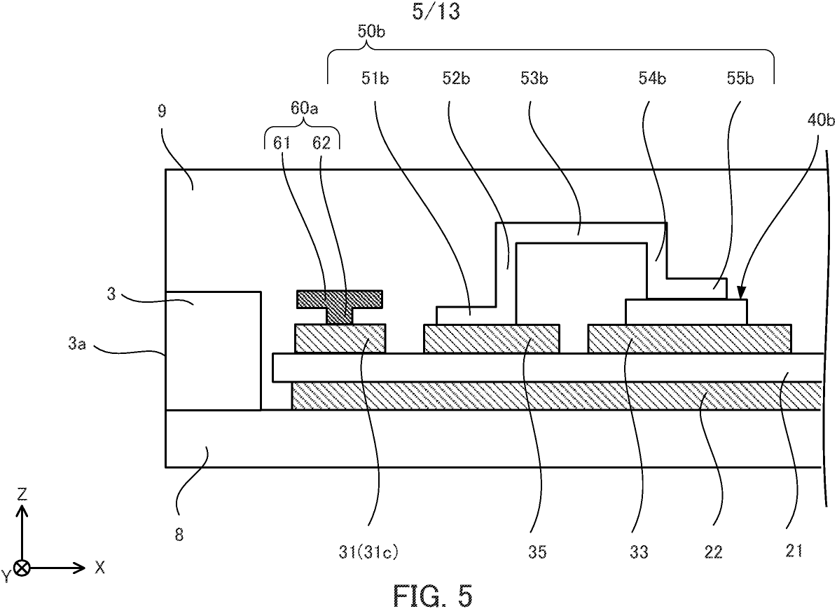

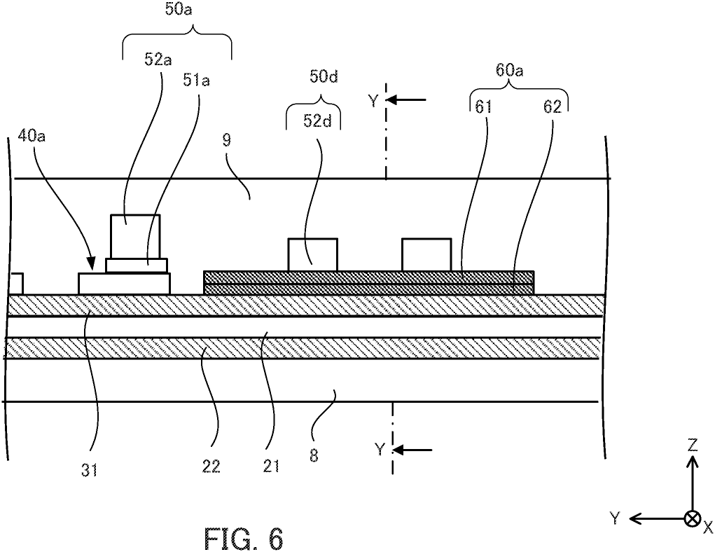

Variation 1-1 according to the first embodiment will be described with reference to FIGS. 5 and 6. FIGS. 5 and 6 are each a sectional view of a main part of a semiconductor module according to variation 1-1 of the first embodiment. FIGS. 5 and 6 correspond to FIGS. 3 and 4, respectively, and are each an enlarged sectional view of a main part of a conductive member 60a. FIG. 5 is a sectional view taken along a dashed-dotted line Y-Y in FIG. 6.

The individual conductive member 60a according to variation 1-1 includes a flat plate portion 61 and a supporting portion 62. The flat plate portion 61 has a flat plate shape. In this case, the width of the flat plate portion 61 in the ±X direction may be the same as or less than the width of the corresponding one of the wiring portions 31c and 32c in the ±X direction. The supporting portion 62 has a columnar shape. The length of the supporting portion 62 in the ±Y direction may be approximately the same as the length of the corresponding one of the wiring portions 32c and 31c in the ±Y direction. The width of the supporting portion 62 in the ±X direction may be less than the width of the flat plate portion 61 in the ±X direction. The individual conductive member 60a according to variation 1-1 has a T-shaped cross section in the ±X direction.

Regarding the individual conductive member 60a, the supporting portion 62 is connected to the rear surface of the flat plate portion 61 and is bonded to the corresponding one of the wiring portions 32c and 31c of the circuit patterns 32 and 31 by using the above-described bonding member. Thus, a current that flows through one of the wiring portions 32c and 31c of the circuit patterns 32 and 31 also flows through the corresponding conductive member 60a. Thus, as in the first embodiment, the wiring portions 32c and 31c each have reduced wiring resistance and loss, and the rise in temperature due to Joule heat is also reduced. That is, it becomes possible to dispose the semiconductor chips 40b and 40d near the circuit patterns 32 and 31 that could be heated, and as a result, the freedom in layout is improved. There are cases in which reducing the volume of the circuit patterns 31 to 36 generates an area having increased wiring resistance. Even in such cases, by forming a conductive member 60a in this area, it becomes possible to reduce the rise in temperature. Thus, variation 1-1 enables downsizing of the semiconductor module 1 while maintaining the reliability of the semiconductor module 1.

In addition, the individual conductive member 60a has a T shape. Thus, when the conductive members 60a are sealed by the sealing member 9, the sealing member 9 also flows under the rear surface of the individual flat plate portion 61. Because the individual conductive member 60a has an anchor effect on the sealing member 9, occurrence of peeling of the sealing member 9 is reduced.

### Variation 1-2

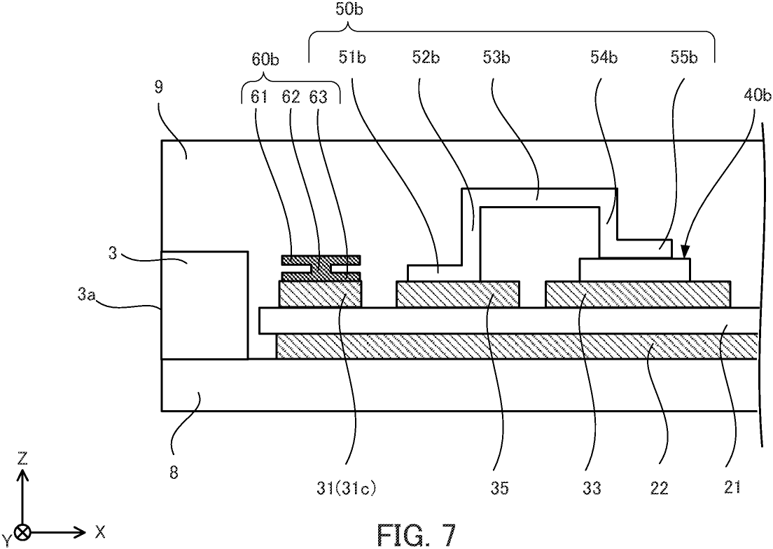

Variation 1-2 of the first embodiment will be described with reference to FIG. 7. FIG. 7 is a sectional view of a main part of a semiconductor module according to variation 1-2 of the first embodiment. FIG. 7 corresponds to FIG. 3 and is an enlarged sectional view of a main part of a conductive member 60b.

The individual conductive member 60b according to variation 1-2 includes a flat plate portion 61, a supporting portion 62, and a flat plate portion 63. That is, the individual conductive member 60b includes a flat plate portion 63 under the supporting portion 62 of the individual conductive member 60a according to variation 1-1. The cross section of the individual conductive member 60b in the ±X direction has an H shape laid on its side.

The width of the individual flat plate portion 63 in the ±X direction may be the same as or less than the width of the corresponding one of the wiring portions 31c and 32c in the ±X direction. One of the flat plate portions 63 is disposed between the connection portion of the wiring portion 31c and the first portion 31a and the connection portion of the wiring portion 31c and the second portion 31b. The other flat plate portion 63 is disposed between the connection portion of the wiring portion 32c and the first portion 32a and the connection portion of the wiring portion 32c and the second portion 32b. The flat plate portions 61 may be the same as the flat plate portions 63.

As is the case with the conductive members 60a, when the conductive members 60b are attached to the wiring portions 32c and 31c of the circuit patterns 32 and 31 by using the above-described bonding member, the wiring portions 32c and 31c each have reduced wiring resistance and loss, and the rise in temperature due to Joule heat is also reduced. In addition, the individual conductive member 60b has a gap between its flat plate portions 61 and 63. Thus, when the conductive members 60a are sealed by the sealing member 9, the sealing member 9 also flows under the rear surface of each of the flat plate portions 61. Because the individual conductive member 60a has an anchor effect on the sealing member 9, occurrence of peeling of the sealing member 9 is reduced. In addition, when the conductive members 60b are used, the flat plate portions 63, each of which is wider than the supporting portions 62 of the conductive members 60a, are bonded to the wiring portions 32c and 31c of the circuit patterns 32 and 31. Thus, the conductive members 60b are bonded to the wiring portions 32c and 31c of the circuit patterns 32 and 31 more stably than the conductive members 60a.

### Variation 1-3

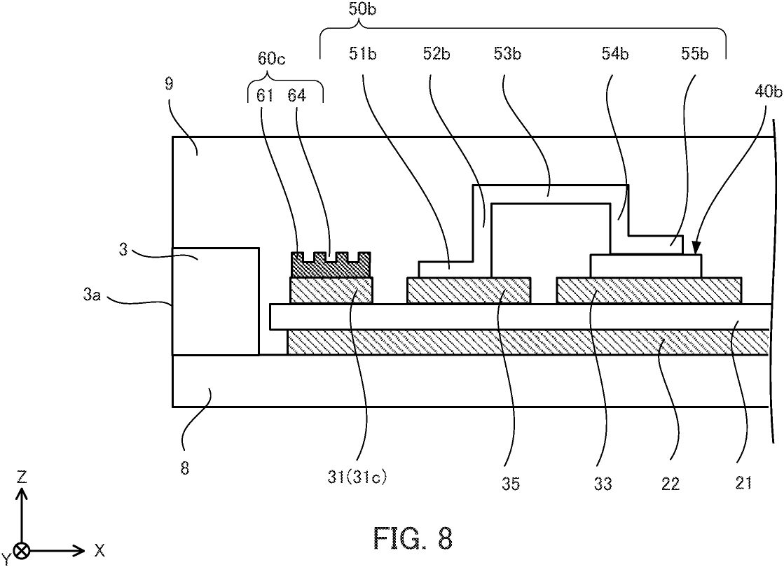

Variation 1-3 of the first embodiment will be described with reference to FIG. 8. FIG. 8 is a sectional view of a main part of a semiconductor module according to variation 1-3 of the first embodiment. FIG. 8 corresponds to FIG. 3 and is an enlarged sectional view of a main part of a conductive member 60c.

The individual conductive member 60c according to variation 1-3 includes a flat plate portion 61 and a plurality of groove portions 64. The flat plate portion 61 is the same as that according to variation 1-1. The plurality of groove portions 64 are formed on the front surface of the flat plate portion 61 along the long sides of the flat plate portion 61. The depth of the individual groove portion 64 is up to 50% of the thickness of the flat plate portion 61 from the front surface of the flat plate portion 61. In addition, the shape of the cross section of the individual groove portion 64 in the ±X direction may be, for example, a U shape or a V shape.

As is the case with the conductive members 60, when the conductive members 60c are attached to the wiring portions 32c and 31c of the circuit patterns 32 and 31 by using the above-described bonding member, the wiring portions 32c and 31c each have reduced wiring resistance and loss, and the rise in temperature due to Joule heat is also reduced. In addition, the individual conductive member 60c includes the plurality of groove portions 64. Thus, when the individual conductive member 60c is sealed by the sealing member 9, the sealing member 9 enters into the plurality of groove portions 64 on the corresponding flat plate portion 61. Because the plurality of groove portions 64 of the individual conductive member 60c have an anchor effect on the sealing member 9, occurrence of peeling of the sealing member 9 is reduced.

Instead of the plurality of groove portions 64 formed on the flat plate portion 61 of the individual conductive member 60c, a plurality of protruding portions may be formed on the entire front surface of the individual flat plate portion 61. In this way, too, the same anchor effect is achieved. The individual protruding portion may have a prismatic shape, a cylindrical shape, a conical shape, or a circular truncated cone shape, for example. Alternatively, instead of the plurality of groove portions 64, a plurality of concave portions may be formed on the entire front surface of the individual flat plate portion 61. The plurality of groove portions 64 (and protruding portions) may be formed on the front surface of the individual flat plate portion 61 according to variation 1-1 or 1-2.

### Second Embodiment

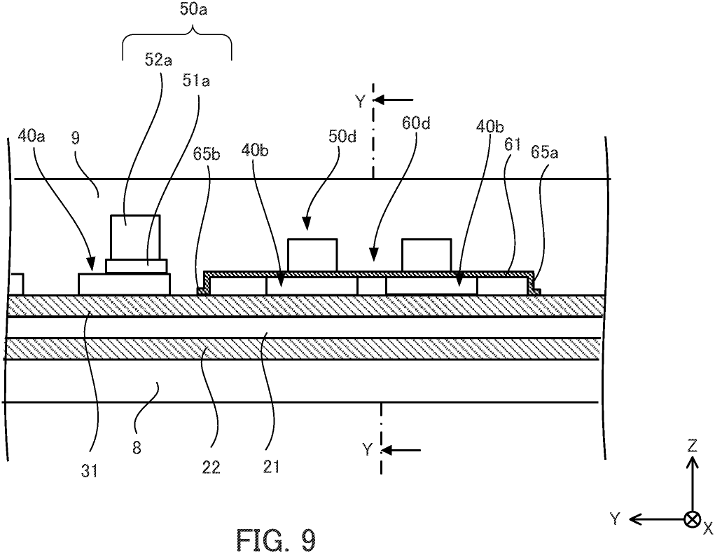

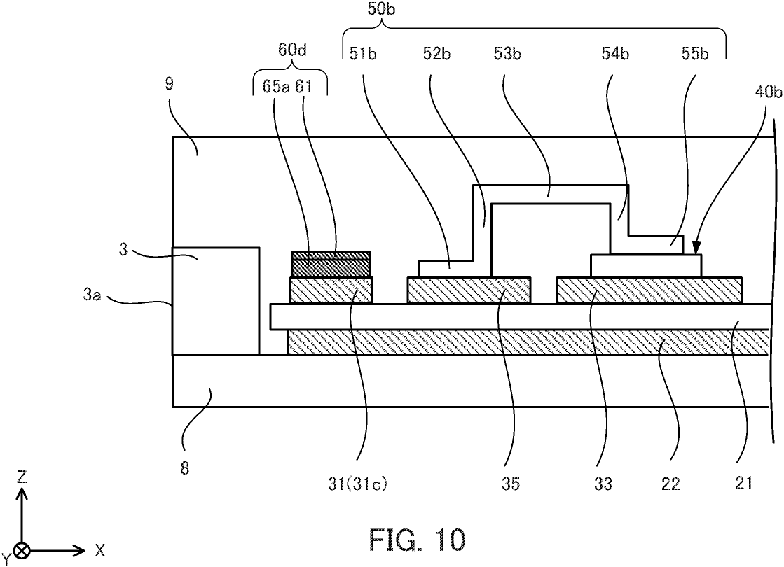

A second embodiment will be described with reference to FIGS. 9 and 10. According to the second embodiment, conductive members different from the conductive members 60 according to first embodiment are used. FIGS. 9 and 10 are each a sectional view of a main part of a semiconductor module according to the second embodiment. FIGS. 9 and 10 correspond to FIGS. 4 and 3, respectively, and are each an enlarged sectional view of a main part of a conductive member 60d. FIG. 10 is a sectional view of the main part taken along a dashed-dotted line Y-Y in FIG. 9. The second embodiment differs from the first embodiment only in the conductive members 60. The other components of this semiconductor module 1 are the same as those in FIGS. 1 to 4. This semiconductor module 1 has a plan view and sectional views similar to those illustrated in FIGS. 1, 3, and 4.

The individual conductive member 60d according to the second embodiment includes a flat plate portion 61 and leg portions 65a and 65b, each of which is formed at a tip portion of the flat plate portion 61 in the longitudinal direction of the flat plate portion 61. That is, the individual conductive member 60d is formed in a bridge connecting the two end portions of the corresponding one of the wiring portions 32c and 31c of the circuit patterns 32 and 31 in the ±Y direction. That is, the individual flat plate portion 61 is away from the front surface of the corresponding one of the circuit patterns 32 and 31 in the +Z direction. That is, there is a gap between the individual flat plate portion 61 and the front surface of the corresponding one of the circuit patterns 32 and 31.

The individual flat plate portion 61 is the same as the individual flat plate portion 61 according to the first embodiment. That is, the width of the individual flat plate portion 61 in the ±X direction may be the same as or less than the width of the corresponding one of the wiring portions 31c and 32c in the ±X direction. The length of the individual flat plate portion 61 is the same as or less than the length between the connection portion of the corresponding wiring portion 31c or 32c and the corresponding first portion 31a or 32a and the connection portion of the corresponding wiring portion 31c or 32c and the corresponding second portion 31b or 32b. It is preferable that the length of the individual flat plate portion 61 be the same as the length between the connection portion of the corresponding wiring portion 31c or 32c and the corresponding first portion 31a or 32a and the connection portion of the corresponding wiring portion 31c or 32c and the corresponding second portion 31b or 32b.

The leg portions 65a and 65b are formed integrally with the two end portions of the individual flat plate portion 61 in the ±Y direction. Each leg portion 65a is bonded from the connection portion of the corresponding wiring portion 31c or 32c and the corresponding first portion 31a or 32a to an area in the corresponding first portion 31a or 32a. Each leg portion 65b is bonded from the connection portion of the corresponding wiring portion 31c or 32c and the corresponding second portion 31b or 32b to an area in the corresponding second portion 31b or 32b. In this way, the individual flat plate portion 61 faces the corresponding wiring portion 31c or 32c, and the bonding areas of the leg portions 65a and 65b are ensured on the circuit patterns 32 and 31. The leg portions 65a and 65b are bonded by using the above bonding member or ultrasonic bonding. The leg portions 65a and 65b may have any shape as long as the leg portions 65a and 65b are properly bonded to the wiring portions 32c and 31c of the circuit patterns 32 and 31. Examples of the shape include an L shape in side view (see FIG. 9). In addition, the height of the leg portions 65a and 65b from the circuit patterns 32 and 31 may be approximately the same as the thickness of the semiconductor chips 40a to 40d.

When the conductive members 60d are disposed on the wiring portions 32c and 31c of the circuit patterns 32 and 31, currents that flow through the wiring portions 32c and 31c also flow through the conductive members 60d. Thus, the wiring portions 32c and 31c each have reduced wiring resistance and loss, and the rise in temperature due to Joule heat is also reduced. That is, it becomes possible to dispose the semiconductor chips 40b and 40d near the circuit patterns 32 and 31 that could be heated, and as a result, the freedom in layout is improved. There are cases in which reducing the volume of the circuit patterns 31 to 36 generates an area having increased wiring resistance. Even in such cases, by forming a conductive member 60d in this area, it becomes possible to reduce the rise in temperature.

In addition, the semiconductor chips 40a to 40d (or at least one of the semiconductor chips 40a to 40d) may be located in the gap between the bridge-type conductive members 60d and the wiring portions 32c and 31c of the circuit patterns 32 and 31. In this connection, FIG. 9 illustrates the case where the semiconductor chip 40b is located in the gap between the conductive member 60d and the circuit pattern 31. In this case, a certain insulating distance needs to be maintained between the conductive members 60d and the semiconductor chips 40a to 40d. Thus, the freedom in disposing the semiconductor chips 40a to 40d is further improved. There are cases in which reducing the volume of the circuit patterns 31 to 36 generates an area having increased wiring resistance. Even in such cases, by forming a conductive member 60d in this area, it becomes possible to reduce the rise in temperature. Thus, the second embodiment enables further downsizing of the semiconductor module 1 while maintaining the reliability of the semiconductor module 1.

While the above description assumes that the individual conductive member 60d includes a single flat plate portion 61 having a flat plate shape, the number of flat plate portions 61 and the shape of the individual flat plate portion 61 are not limited to any particular number or shape. Next, variations indicating various modes of the conductive member 60d will be described. In each of the following variations, only the conductive members 60d differ. The other components of the semiconductor module 1 are the same as those in FIGS. 1 to 4.

### Variation 2-1

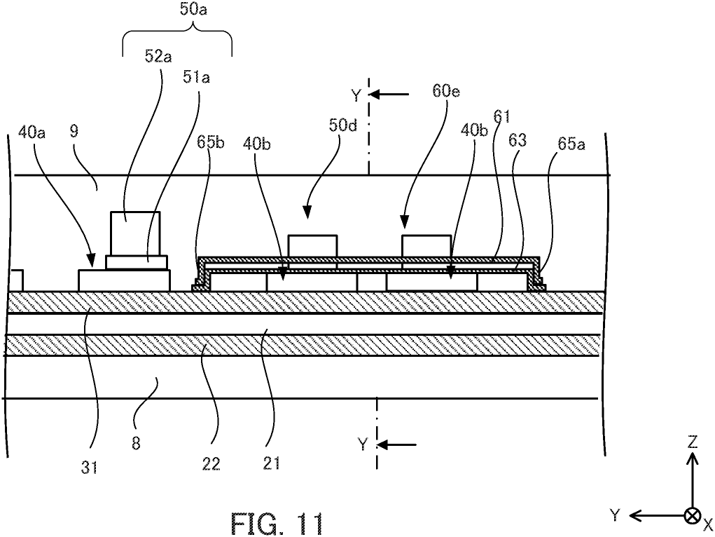

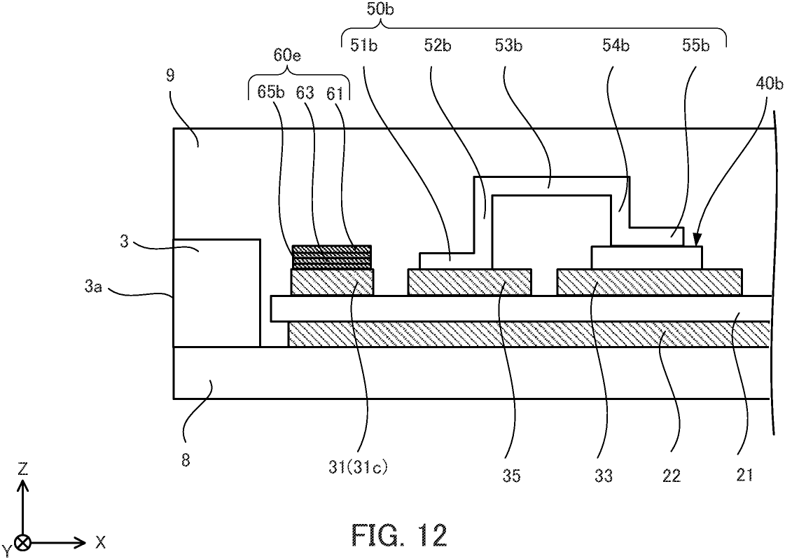

Variation 2-1 according to the second embodiment will be described with reference to FIGS. 11 and 12. FIGS. 11 and 12 are each a sectional view of a main part of a semiconductor module according to variation 2-1 of the second embodiment. FIGS. 11 and 12 correspond to FIGS. 4 and 3, respectively, and are each an enlarged sectional view of a main part of a conductive member 60e. FIG. 12 is a sectional view of the main part taken along a dashed-dotted line Y-Y in FIG. 11.

The individual conductive member 60e according to variation 2-1 includes two flat plate portions 61 and 63 and leg portions 65a and 65b. The flat plate portion 63 is formed in the -Z direction of the flat plate portion 61. That is, the conductive member 60e is formed by forming the flat plate portion 63 under the flat plate portion 61 of the conductive member 60d with a gap between the flat plate portions 61 and 63. That is, the leg portions 65a and 65b connect the two tip portions of each of the flat plate portions 61 and 63 in the ±Y direction. The leg portions 65a and 65b may have any shape as long as the leg portions 65a and 65b properly connect the flat plate portions 61 and 63. For example, in FIG. 11, two conductive members 60d as illustrated in FIG. 9 are overlapped with each other in the Z direction. In this connection, even in the variation 2-1, the semiconductor chips 40a to 40d (or at least one of the semiconductor chips 40a to 40d) may be located in the gap between the conductive member 60e and the wiring portions 32c and 31c of the circuit patterns 32 and 31. FIG. 11 illustrates the case where the semiconductor chip 40b is located in the gap between the conductive member 60e and the circuit pattern 31.

As in the second embodiment, in the case of the conductive members 60e, too, the wiring portions 32c and 31c each have reduced wiring resistance and loss, and the rise in temperature due to Joule heat is also reduced. In addition, in the case of the conductive members 60d according to the second embodiment, a difference (current imbalance) may be caused between the current flowing through the wiring portion 32c of the circuit pattern 32 and the current flowing through the wiring portion 31c of the circuit pattern 31, depending on the difference between the wiring resistances of the wiring portions 32c and 31c. Since the individual conductive member 60e according to variation 2-1 includes two flat plate portions 61 and 63, the current imbalance is reduced.

The individual conductive member 60e according to variation 2-1 includes the two flat plate portions 61 and 63 as an example. However, the number of flat plate portions of the individual conductive member 60e is not limited to 2. Three or more flat plate portions may be formed to overlap each other with a gap between each pair of flat plate portions. In this case, a flat plate portion farther away from the corresponding circuit pattern may be formed to have a larger cross-sectional area. In this way, the current imbalance is further reduced.

### Variation 2-2

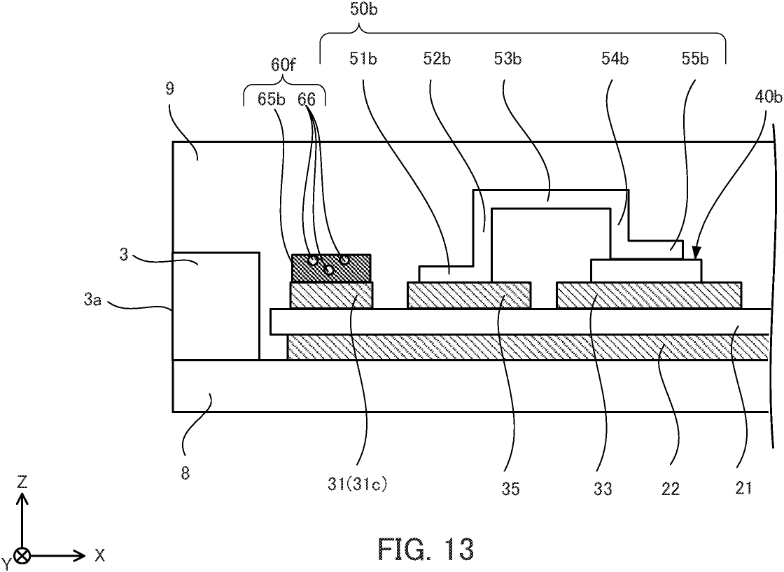

Variation 2-2 of the second embodiment will be described with reference to FIG. 13. FIG. 13 is a sectional view of a main part of a semiconductor module according to variation 2-2 of the second embodiment. FIG. 13 corresponds to FIG. 4 and is an enlarged sectional view of a main part of a conductive member 60f. A side view seen in the +X direction in FIG. 13 is similar to FIG. 11, for example. Thus, FIG. 13 is similar to a sectional view of the main part taken along a dashed-dotted line Y-Y in FIG. 11.

The individual conductive member 60f according to variation 2-2 includes a plurality of cylindrical portions 66 and leg portions 65a and 65b. FIG. 13 illustrates a leg portion 65b. The plurality of cylindrical portions 66 are formed in levels such that more cylindrical portions 66 are formed in a higher level in the +Z direction. According to variation 2-2, a single cylindrical portion 66 is formed in a level, and on this cylindrical portion 66, two cylindrical portions 66 extending side by side are formed in a higher level. The leg portions 65a and 65b are formed at one end and the other end of the individual cylindrical portion 66 in the longitudinal direction, as in variation 2-1.

In the case of the conductive members 60f, too, as in variation 2-1, the wiring portions 32c and 31c each have reduced wiring resistance and loss, and the rise in temperature due to Joule heat is also reduced. In addition, since the individual conductive member 60f according to variation 2-2 includes the plurality of cylindrical portions 66, the above-described current imbalance is reduced. In particular, a skin effect appears in the cylindrical portions 66 of the conductive members 60f. Thus, the resistance to the current that flows through the individual cylindrical portion 66 decreases, and the current flows through the individual cylindrical portion 66 more easily.

In addition, according to variation 2-2, more cylindrical portions 66 are formed in a higher level in the +Z direction. Alternatively, a plurality of cylindrical portions 66 may be accumulated in a column in the +Z direction with a gap between each pair of cylindrical portions 66, to increase the cross-sectional area of the individual cylindrical portion 66.

The semiconductor device having any one of the above-described structures is able to reduce increase in wiring resistance, prevent occurrence of failure, and prevent deterioration in reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip that has a first main electrode on a rear surface thereof and a second main electrode on a front surface thereof; and
a wiring layer electrically connected to at least one of the first main electrode or the second main electrode, the wiring layer including a conductive member disposed on a front surface thereof.

2. The semiconductor device according to claim 1, wherein the wiring layer includes
a first portion that has, on a front surface thereof, a chip area to which the rear surface of the semiconductor chip is bonded,
a second portion that has, on a front surface thereof, a terminal area to which an external connection terminal is bonded, and
a wiring portion that connects the first portion and the second portion, the wiring portion including the conductive member on a front surface thereof.

3. The semiconductor device according to claim 2, wherein the conductive member has a flat plate portion that has a flat plate shape extending along the wiring portion and that has a width equal to or less than a width of the wiring portion in a direction perpendicular to a direction in which a current in the wiring layer flows in a plan view of the semiconductor device.

4. The semiconductor device according to claim 3, wherein the flat plate portion of the conductive member is directly disposed on the front surface of the wiring portion.

5. The semiconductor device according to claim 3, wherein
the conductive member further includes a supporting portion that extends along the wiring portion and is disposed on a rear surface of the flat plate portion to connect the flat plate portion and the wiring portion, and
the conductive member has a T shape in a sectional view of the semiconductor device.

6. The semiconductor device according to claim 3, wherein a front surface of the flat plate portion of the conductive member has a plurality of grooves.

7. The semiconductor device according to claim 3, wherein
the flat plate portion is formed above the front surface of the wiring portion with a gap therebetween, and
the conductive member further includes a pair of leg portions, one of which connects one end portion of the flat plate portion and the front surface of the wiring portion, and the other one of which connects another end portion of the flat plate portion and the front surface of the wiring portion.

8. The semiconductor device according to claim 7, wherein the flat plate portion of the conductive member is provided in plurality, and one of the plurality of flat plate portions is disposed on top of an other of the plurality of flat plate portions with a gap therebetween above the front surface of the wiring portion.

9. The semiconductor device according to claim 8, wherein a cross-sectional area of the one of the plurality of flat plate portions is greater than a cross-sectional area of the other one of the plurality of flat plate portions.

10. The semiconductor device according to claim 2, wherein the conductive member further includes
a cylindrical portion that has a cylindrical shape, a diameter of which is equal to or less than a width of the wiring portion in a direction perpendicular to a direction in which a current in the wiring layer flows in a plan view of the semiconductor device, the cylindrical portion being disposed above the front surface of the wiring portion with a gap therebetween and extending along the wiring portion, and
a pair of leg portions that connect respective ones of two end portions of the cylindrical portion and the front surface of the wiring portion.

11. The semiconductor device according to claim 10, wherein the cylindrical portion of the conductive member is provided in plurality, and one of the plurality of cylindrical portions is disposed on top of an other of the plurality of cylindrical portions with a gap therebetween above the front surface of the wiring portion.

12. The semiconductor device according to claim 11, wherein a cross-sectional area of the one of the plurality of cylindrical portions is greater than a cross-sectional area of the other one of the plurality of cylindrical portions.

13. The semiconductor device according to claim 10, wherein the cylindrical portion of the conductive member is provided in plurality, and the plurality of cylindrical portions are provided in a plurality of heights from the front surface of the wiring portion such that more cylindrical portions are provided side by side in a higher level.
